(19) United States
(12) Patent Application Publication
(10) Pub. No.: US 2019/0101588 A1
(43) Pub. Date: Apr. 4, 2019

(54) VISION ALIGNMENT SYSTEM OUTSIDE OF TEST SITE

(71) Applicant: Delta Design, Inc., Poway, CA (US)

(72) Inventors: Kexiang Ken Ding, San Diego, CA (US); Kenneth B. Uekert, Ramona, CA (US); Michael Anthony Laver, El Cajon, CA (US); Samer Kabbani, Encinitas, CA (US)

(73) Assignee: Delta Design, Inc., Poway, CA (US)

(21) Appl. No.: 15/722,736

(22) Filed: Oct. 2, 2017

(51) Int. Cl. G01R 31/28; G01R 1/04

(52) U.S. Cl. CPC G01R 31/2891; G01R 1/0433; G01R 31/2887

(57) ABSTRACT

A system includes: a bottom contactor assembly; a top contactor assembly; and a contactor vision alignment system located separate from a test site of an integrated circuit device testing system. The contactor vision alignment system includes: a downward-looking camera, an upward-looking camera, an adjustment mechanism configured to move the top contactor assembly, and a controller configured to: determine a first offset between a bottom side integrated circuit device contact array and a bottom contactor contact array, cause the adjustment mechanism to align the bottom side integrated circuit device contact array with the bottom contactor contact array based on the determined first offset, determine a second offset between the top contactor contact array and a top side integrated circuit device contact array, and cause the adjustment mechanism to align the top contactor with respect to the top side device contact array based on the determined second offset.

### BACKGROUND

The present disclosure relates generally to a vision alignment system for use with an integrated circuit (IC) device testing system, and more particularly to vision alignment system located outside of a test site of the IC device testing system. Embodiments include a contactor vision alignment system for use with an IC device testing system, and a clamping mechanism for use in such a contactor vision alignment system.

Semiconductor Automatic Testing Equipment (ATE) typically has vision alignment mechanisms in the test interface region, called the test site, which includes test sockets, transport heads, in addition to the vision cameras, lights, optics and actuators. Vision alignment is used to accurately align the test site socket pins to the IC contacts due to the fine pitch spacing (e.g., less than 0.3 mm)

Collocating the vision alignment mechanism in the test site is primarily done to minimize the error stack induced with IC transportation steps resulting in mis-contacts.

### SUMMARY

The drawback to including a visional alignment mechanism in the test site is that the test region becomes very complicated and congested with mechanisms. If temperature testing is required, this adds further complexities to the test region.

Further challenges arise when both top and bottom side contacts exist on the IC, with fine pitch spacing of the IC contacts requiring further alignment actuators, cameras and process steps.

To reduce complexity in the test site, the present disclosure describes vision alignment methods and apparatuses to accurately and repeatedly align the IC device contacts to the top and bottom contactor test contacts at a location outside the test handler itself—that is, outside the test site at which IC device testing is performed. The vision aligned IC device is clamped between the top and bottom contactors in the contactor visional alignment system, and held in the aligned position while being transported to the testing system and during testing.

In one embodiment, a system includes: a bottom contactor assembly comprising a bottom contactor contact array, a top contactor assembly comprising a top contactor contact array; and a contactor vision alignment system located separate from a test site of an integrated circuit device testing system. The contactor vision alignment system includes: a downward-looking camera configured to view the bottom contactor assembly, an upward-looking camera configured to view the top contactor assembly, an adjustment mechanism configured to move the top contactor assembly, and a controller configured to, based on data received from the downward-looking camera and the upward-looking camera: determine an offset between a bottom side integrated circuit device contact array and the bottom contactor contact array, cause the adjustment mechanism to align the bottom side integrated circuit device contact array with the bottom contactor contact array based on the determined offset between the bottom side device contact array and the bottom contactor contact array, determine an offset between the top contactor contact array and a top side integrated circuit device contact array, and cause the adjustment mechanism to align the top contactor with respect to the top side device contact array based on the determined offset between the top side device contact array and the top contactor contact array.

In one aspect, the top contactor assembly comprises at least two top contactor assembly fiducials, each of which is visible from both a top side and a bottom side of the top contactor assembly, the bottom contactor assembly comprises at least two bottom contactor assembly fiducials, the adjustment mechanism comprises at least two adjustment mechanism fiducials, the controller is configured to determine the offset between the bottom side device contact array and the bottom contactor contact array by performing steps that include: determining an offset between the bottom contactor contact array and the at least two bottom contactor assembly fiducials, based on data from the downward-looking camera, and determining an offset between the bottom side device contact array and the at least two adjustment mechanism fiducials while the integrated circuit device is held by the adjustment mechanism, based on data from the upward-looking camera. The controller is configured to determine the offset between the top contactor contact array and the top side device contact array by performing steps that include: determining an offset between the top contactor contact array and the at least two adjustment mechanism fiducials while the top contactor assembly is held by the adjustment mechanism, based on data from the upward-looking camera, and determining an offset between the top side device contact array and the at least two bottom contactor assembly fiducials while the integrated circuit device is located in the bottom contactor assembly, based on data from the downward-looking camera.

In one aspect, the controller is further configured perform a top vision alignment calibration process that includes: picking the top contactor assembly and moving the top contactor assembly above the upward-looking camera, determining an offset between the at least two top contactor assembly fiducials and the at least two adjustment mechanism fiducials, based on data from the upward-looking camera, placing the top contactor assembly into the bottom contactor assembly, determining an offset between the at least two bottom contactor assembly fiducials and the at least two top contactor assembly fiducials, based on data from the downward-looking camera, and calculating an offset between the at least two bottom contactor assembly fiducials and the at least two adjustment mechanism fiducials, based on the determined offset between the at least two top contactor assembly fiducials and the at least two adjustment mechanism fiducials and the determined offset between the at least two bottom contactor assembly fiducials and the at least two top contactor assembly fiducials.

In one aspect, the controller is configured to use the calculated offset between the at least two bottom contactor assembly fiducials and the at least two adjustment mechanism fiducials in both (i) determining the offset between the bottom side device contact array and the bottom contactor contact array, and (ii) determining the offset between the top contactor contact array and the top side device contact array.

In one aspect, the system further includes: a locking mechanism configured to attach the top and bottom contactor assemblies to each other while the integrated circuit device is located between the top contactor and the bottom contactor, and while the bottom side device contact array is connected to the bottom contactor contact array and the top side device contact array is connected to the top contactor contact array.

In another embodiment, a method of performing vision alignment of an integrated circuit device includes: providing a bottom contactor assembly comprising a bottom contactor contact array; providing a top contactor assembly comprising a top contactor contact array; providing a contactor vision alignment system located separate from a test site of an integrated circuit device testing system, the contactor vision alignment system including: a downward-looking camera configured to view the bottom contactor assembly, an upward-looking camera configured to view the top contactor assembly, an adjustment mechanism configured to move the top contactor assembly, and a controller; using the controller, and based on data received from the downward-looking camera and the upward-looking camera: determining an offset between the bottom side device contact array and the bottom contactor contact array, causing the adjustment mechanism to align the bottom side device contact array with the bottom contactor contact array based on the determined offset between the bottom side device contact array and the bottom contactor contact array, determining an offset between the top contactor contact array and the top side device contact array, and causing the adjustment mechanism to align the top contactor with respect to the top side device contact array based on the determined offset between the top side device contact array and the top contactor contact array.

In one aspect, the top contactor assembly comprises at least two top contactor assembly fiducials, each of which is visible from both a top side and a bottom side of the top contactor assembly, the bottom contactor assembly comprises at least two bottom contactor assembly fiducials, the adjustment mechanism comprises at least two adjustment mechanism fiducials. The step of determining the offset between the bottom side device contact array and the bottom contactor contact array includes: determining an offset between the bottom contactor contact array and the at least two bottom contactor assembly fiducials, based on data from the downward-looking camera, and determining an offset between the bottom side device contact array and the at least two adjustment mechanism fiducials while the integrated circuit device is held by the adjustment mechanism, based on data from the upward-looking camera. The step of determining the offset between the top contactor contact array and the top side device contact array includes: determining an offset between the top contactor contact army and the at least two adjustment mechanism fiducials while the top contactor assembly is held by the adjustment mechanism, based on data from the upward-looking camera, and determining an offset between the top side device contact array and the at least two bottom contactor assembly fiducials while the integrated circuit device is located in the bottom contactor assembly, based on data from the downward-looking camera.

In one aspect, the method further includes: performing a top vision alignment calibration process that includes: picking the top contactor assembly and moving the top contactor assembly above the upward-looking camera, determining an offset between the at least two top contactor assembly fiducials and the at least two adjustment mechanism fiducials, based on data from the upward-looking camera, placing the top contactor assembly into the bottom contactor assembly, determining an offset between the at least two bottom contactor assembly fiducials and the at least two top contactor assembly fiducials, based on data from the downward-looking camera, and calculating an offset between the at least two bottom contactor assembly fiducials and the at least two adjustment mechanism fiducials, based on the determined offset between the at least two top contactor assembly fiducials and the at least two adjustment mechanism fiducials and the determined offset between the at least two bottom contactor assembly fiducials and the at least two top contactor assembly fiducials.

In one aspect, the calculated offset between the at least two bottom contactor assembly fiducials and the at least two adjustment mechanism fiducials is used in both (i) determining the offset between the bottom side device contact array and the bottom contactor contact array, and (ii) determining the offset between the top contactor contact array and the top side device contact array.

In one aspect, the method further includes: using a locking mechanism to attach the top and bottom contactor assemblies to each other while the integrated circuit device is located between the top contactor and the bottom contactor, and while the bottom side device contact array is connected to the bottom contactor contact array and the top side device contact array is connected to the top contactor contact array; and transferring top and bottom contactor assemblies, with the integrated circuit device located therebetween, to a test site of an integrated circuit device testing system.

In another embodiment, a clamping mechanism is configured to hold an integrated circuit device having a bottom side device contact array and a top side device contact array. The clamping mechanism includes: a bottom contactor assembly including: a bottom contactor assembly frame, and a bottom contactor attached to the bottom contactor assembly frame, the bottom contactor comprising a bottom contactor contact array; a top contactor assembly including: a clamping apparatus, and a top contactor fixed to the clamping apparatus, the top contactor comprising a top contactor contact array; and a locking mechanism configured to removably attach the top and bottom contactor assemblies to each other while the integrated circuit device is located between the top contactor and the bottom contactor, and while the bottom side device contact array is connected to the bottom contactor contact array and the top side device contact array is connected to the top contactor contact array.

In one aspect, the clamping apparatus of the top contactor assembly includes: a clamping plate configured to contact the bottom contactor assembly frame when the top and bottom contactor assemblies are attached to each other, a mounting plate to which the top contactor is fixed, and a vertical compliance member configured to allow the mounting plate and the top contactor to move vertically with respect to the clamping plate, so as to preload the top contactor when the top and bottom contactor assemblies are attached to each other.

In one aspect, the vertical compliance member is a flexure.

In one aspect, the locking mechanism comprises an electromagnetic device.

In one aspect, the locking mechanism comprises an electromagnetic device located in the clamping plate.

In one aspect, the locking mechanism comprises a vacuum device, an air pressure device, or a mechanical latch.

In one aspect, the top contactor assembly comprises at least two top contactor assembly fiducials, each of which is visible from both a top side and a bottom side of the top contactor assembly.

In one aspect, the at least two top contactor assembly fiducials are located on the top contactor.

In one aspect, the top contactor comprises at least two projections that extend laterally beyond a periphery of the clamping apparatus, and each of the at least two top contactor assembly fiducials is located on a respective one of the projections at a location outside the periphery of the clamping apparatus.

In one aspect, the bottom contactor assembly comprises at least two bottom contactor assembly fiducials.

In one aspect, the clamping mechanism is movable as a unit while the top and bottom contactor assemblies are attached to each other via the locking mechanism.

### BRIEF DESCRIPTION OF THE DRAWINGS

FIG. 1 is a perspective view of a system that includes an integrated circuit (IC) device testing system and a contactor vision alignment system.

FIG. 2 is a perspective view of an adjustment mechanism (i.e., a pick-and-place head) for the contactor vision alignment system of FIG. 1.

FIG. 3 is a perspective view of a clamping mechanism that includes a top contactor assembly and bottom contactor assembly, according to one embodiment, along with an IC device.

FIG. 4A is a bottom perspective view the top contactor assembly shown in FIG. 3. FIG. 4B is a top perspective view the top contactor assembly shown in FIG. 3.

FIG. 5 is a bottom perspective view of the attachment plate with two attached bushings.

FIG. 6A is a top perspective view of first, circular bushing for maintaining a correct origin position. FIG. 6B is a top perspective view of a second, oval bushing for maintaining a correct angular position.

FIG. 7A is a bottom perspective view of a top contactor assembly according to another embodiment, being held by an adjustment mechanism. FIG. 7B is a top perspective view of a bottom contactor assembly with a top contactor assembly located therein.

FIG. 8 is a top perspective view of a portion of the contactor vision alignment system shown in FIG. 1, according to one embodiment.

FIG. 9 shows an example of an expected linear grid motion of the actuators and an imaged non-linear grid motion of the actuators during the calibration process.

### DETAILED DESCRIPTION

Embodiments of the present invention will be described below with reference to the accompanying drawings. It should be understood that the following description is intended to describe exemplary embodiments of the invention, and not to limit the invention.

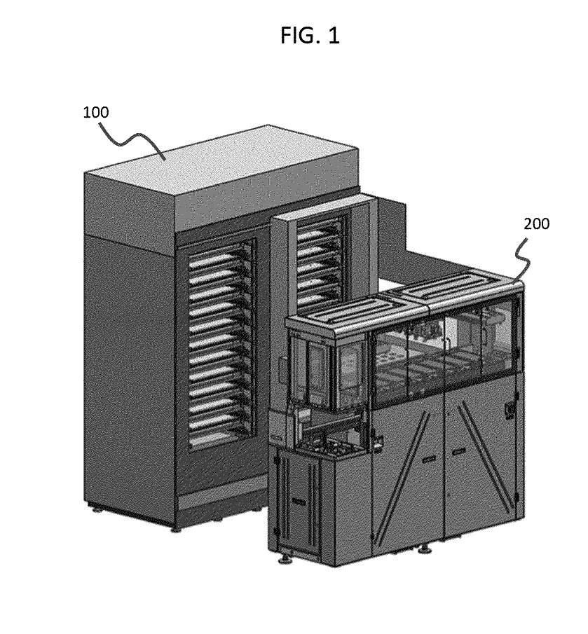

FIG. 1 is a perspective view of a system that includes an integrated circuit (IC) device testing system 100 and contactor vision alignment system 200. The device testing system 100 includes testers with top and bottom pogo pins for electronically testing the devices from the I/O site contactor vision alignment system 200. The contactor vision alignment system 200 may be, for example, an input/output site contactor vision alignment system, located at an input/output site.

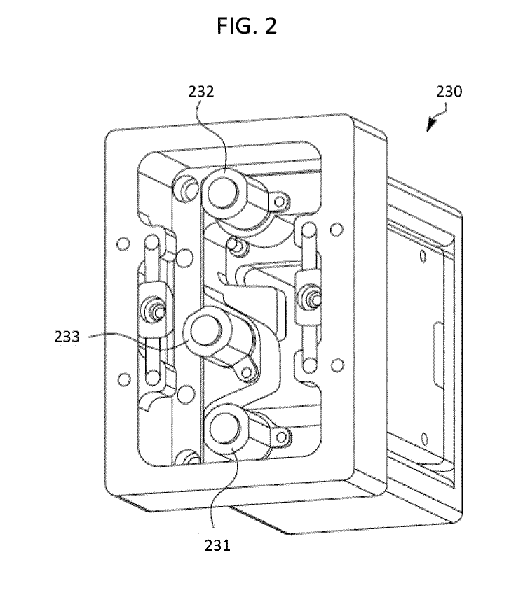

FIG. 2 is a perspective view of an adjustment mechanism 230 (i.e., a pick-and-place head) for the contactor vision alignment system of FIG. 1. As shown in FIG. 2, the adjustment mechanism 230 includes three linear actuators 231, 232, 233, built into an alignment head, which are configured to correct for translation and rotation offsets of an IC device or top contactor assembly, described in more detail below. The average movement of actuators 231, 232 determines the X-direction offset adjustment of the IC device or top contactor assembly. The movement of actuator 233 determines the Y-direction offset adjustment of the IC device or top contactor assembly. The difference in movement between actuators 231, 232 determines the angular offset adjustment of the IC device or top contactor assembly. The actuating amounts are determined based on an offset between contact arrays of the top contactor assembly (or fiducials of the top contactor assembly), a bottom contactor assembly (or fiducials of the bottom contactor assembly), and an IC device under test.

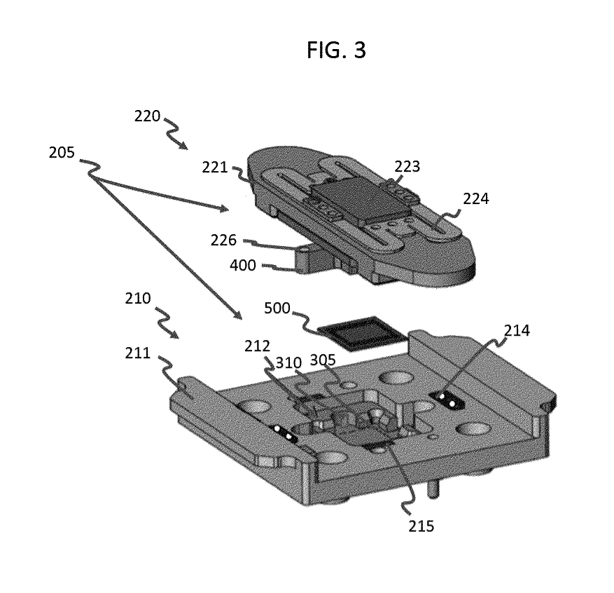

The contactor vision alignment system 200 utilizes one or more clamping mechanisms 205. FIG. 3 is a perspective view of a clamping mechanism 205 that includes a top contactor assembly 220 and bottom contactor assembly 210, according to one embodiment, along with an IC device 500. The IC device 500 has a top side device contact array, which is visible in FIG. 2, and a bottom side device contact array, which is not visible in FIG. 3.

The bottom contactor assembly 210 of the clamping mechanism 205 includes a bottom contactor assembly frame 211, and a bottom contactor 212 attached to the bottom contactor assembly frame 211. The bottom contactor 212 includes a bottom contactor contact array 305. The bottom contactor 212 and frame 211 form a socket into which an IC device 500 can be placed. The bottom contactor assembly 210 further includes two guide pins 310, configured to engage with corresponding zero-clearance bushings 223a and 223b of the top contactor assembly 220, as discussed below.

The bottom contactor assembly 210 includes at least two fiducials 214. The bottom contactor assembly fiducials 214 are configured to be easily visible using a downward-facing camera, as discussed in further detail below. In the embodiment shown in FIG. 3, the bottom contactor assembly fiducials 214 are located on the bottom contactor assembly frame 211.

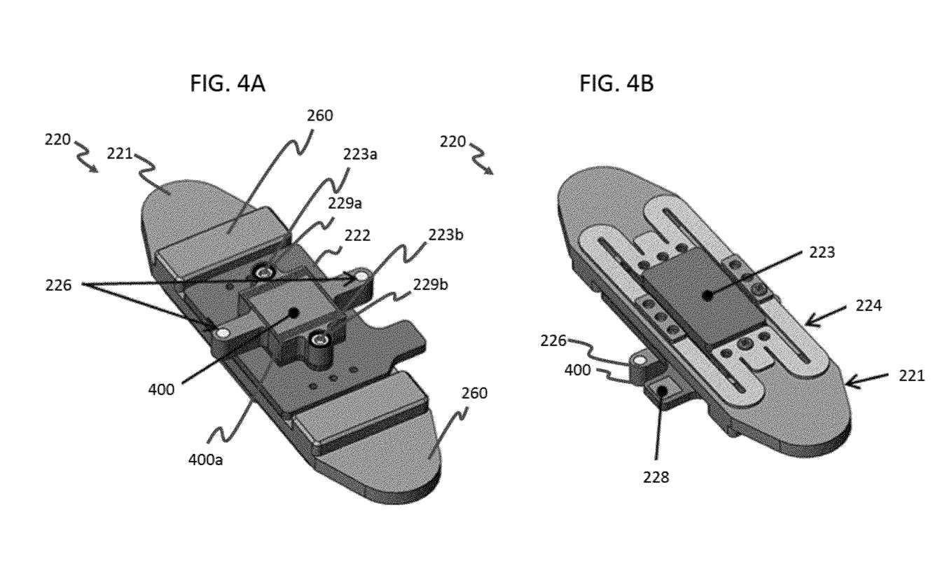

FIG. 4A is a bottom perspective view the top contactor assembly 220 shown in FIG. 3. FIG. 4B is a top perspective view the top contactor assembly 220 shown in FIG. 3. The top contactor assembly 220 includes a clamping plate 221, a vertical movement plate 222, an adjustment mechanism attachment plate 223, a vertical compliance member 224 attaching the clamping plate 221 to the vertical movement plate 222, and a top contactor 400 fixed to the vertical movement plate 222. The top contactor 400 includes a top contactor contact array 400a, as shown in FIG. 4A.

The clamping plate 221 is configured to contact the bottom contactor assembly frame 211 when the top and bottom contactor assemblies 210, 220 are attached to each other.

The adjustment mechanism attachment plate 223 is configured to be fixed to the adjustment mechanism 230, such that the attachment plate 223 is movement in a vertical direction by the adjustment mechanism 230, but the attachment plate 223 is not movable in a horizontal direction (that is, there is no X, Y, or angular movement of the attachment plate 223 relative to the adjustment mechanism 230 when the attachment plate 223 is attached to the adjustment mechanism 230).

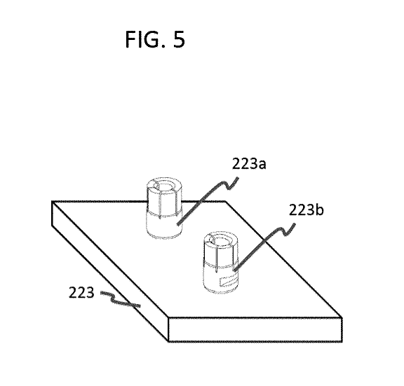

FIG. 5 is a bottom perspective view of the attachment plate 223 with two attached bushings 223a, 223b. The zero-clearance bushings 223a, 223b are configured to extend into two corresponding openings 229a, 229b in the top contactor 400. There is clearance around the bushings 223a, 223b, such that the top contactor 400 and the other elements attached thereto (including the vertical movement plate 222, vertical compliance member 224, and clamping plate 221) are able to move in the horizontal direction relative to the attachment plate 223 and bushings 223a, 223b, even when the bushings 223a, 223b are located in the openings 229a, 229b.

As discussed above, the bottom contactor assembly 210 includes two guide pins 310. When the top contactor assembly 220 is attached to the bottom contactor assembly 210, the guide pins 310 engage with the bushings 223a, 223b.

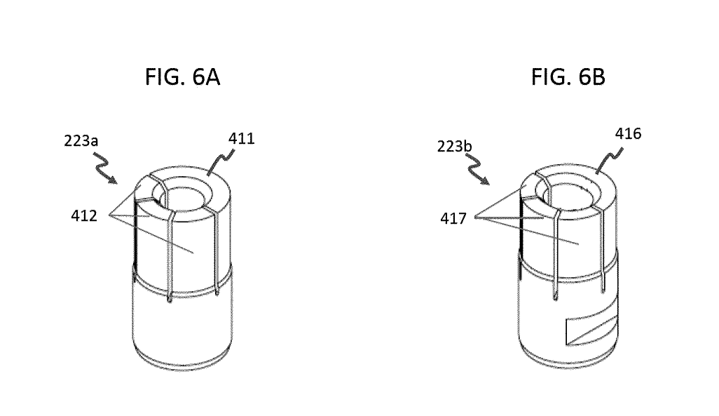

The bushings 223a, 223b are preferably zero-clearance bushings, which mitigates alignment errors. FIG. 6A is a top perspective view of first, circular bushing for maintaining a correct origin position. FIG. 6B is a top perspective view of a second, oval bushing for maintaining a correct angular position. The first bushing 223a, shown in FIG. 6A, contains a half-circular solid (i.e., rigid) bushing piece 411 to determine the origin of the pin-bushing engagement local coordinate system. The second bushing 223b, shown in FIG. 6B, has a half-ovular solid (i.e., rigid) bushing piece 416 used to determine the angle of the pin-bushing local coordinate. Both bushings 223a, 223b have spring-loaded fingers 412, 417 to reference the pins 310 towards the half-circular or half-ovular solid piece 411, 416.

In alternative embodiments, the bushings and guide pins may be interchanged, so that the bushings are on the bottom contactor assembly 210, and the guide pins are on the top contactor assembly 220.

Because the vertical movement plate 222 is attached to the clamping plate 221 via the vertical compliance member 224, the vertical movement plate 222, and thus the top contactor 400, can move vertically when the attachment plate 223 is attached to the adjustment mechanism 230, and the clamping plate 221 is attached to the bottom contactor assembly frame 211. In the embodiment shown in FIGS. 4A and 4B, the vertical compliance member 224 is a flexure. In other embodiments, the vertical compliance member 224 can be a spring or other flexible element.

The top contactor assembly 220 further includes at least two fiducials 226, each of which is visible from both a top side and a bottom side of the top contactor assembly 220 (i.e., “double-sided” fiducials). In the embodiment shown in FIGS. 4A and 4B, the fiducials 226 are located on the top contactor 400. Specifically, the top contactor 400 comprises two projections that extend laterally beyond a periphery of the clamping plate 221 and vertical movement plate 222. Each of the fiducials 226 is located on a respective one of the projections at a location outside the periphery of the clamping plate 221 and vertical movement plate 222, as can be seen in FIGS. 4A and 4B.

The clamping mechanism 205 further includes a locking mechanism 260 configured to removably attach the top and bottom contactor assemblies 210, 220 to each other while the integrated circuit device 500 is located between the top contactor 220 and the bottom contactor 210, and while the bottom side device contact array is connected to the bottom contactor contact array and the top side device contact array is connected to the top contactor contact array 400a. The locking mechanism 260 may be an electromagnetic device, a vacuum device, an air pressure device, or a mechanical latch. In the example shown in FIGS. 4A and 4B, the locking mechanism 260 includes a pair of electromagnetic devices located in the clamping plate 221 of the top contactor assembly 220. The electromagnetic devices can be selectively actuated to clamp the top contactor assembly 220 to the bottom contactor assembly 210. In alternative embodiments, the locking mechanism 260 may be included in the bottom contactor assembly 210 rather than the top contactor assembly 220, or in both the top and bottom contactor assemblies 210, 220. After the locking mechanism 260 is used to attach the top contactor assembly 220 to the bottom contactor assembly 210, the entire clamping mechanism 205, with the IC device 500 clamped therein, is movable as a unit. For example, the clamping mechanism 205 with the IC device 500 can be transferred as a unit to the integrated circuit device testing system 100 for testing, and the alignment between the IC device 500 and the top and bottom contactors 400, 212 can be maintained during the transfer and during testing.

The bottom contactor assembly 210 includes an identification mark 215, and the top contactor assembly 220 includes an identification mark 228. The identification marks 215, 228 can be used to correlate matched pairs of top and bottom contactor assemblies 210, 220 that have been calibrated to one another, as discussed in more detail below.

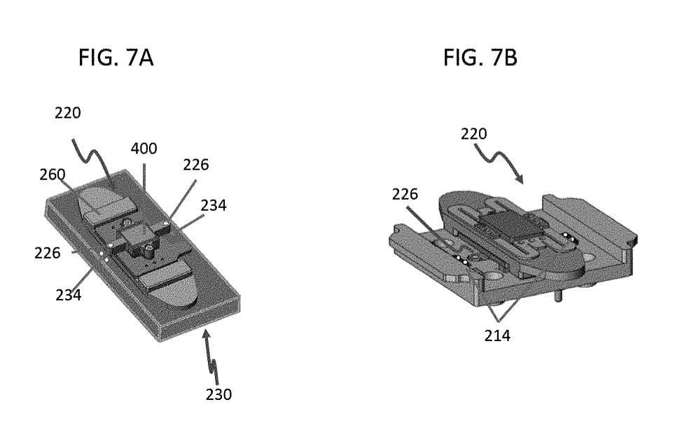

FIG. 7A is a bottom perspective view of a top contactor assembly 220 according to another embodiment, being held by an adjustment mechanism 230. As shown in FIG. 7A, a bottom surface of the adjustment mechanism 230 includes a plurality of fiducials 234, in this case, two fiducials 234 on each opposing side of the bottom surface. FIG. 7B is a top perspective view of a bottom contactor assembly 210 with a top contactor assembly 220 located therein.

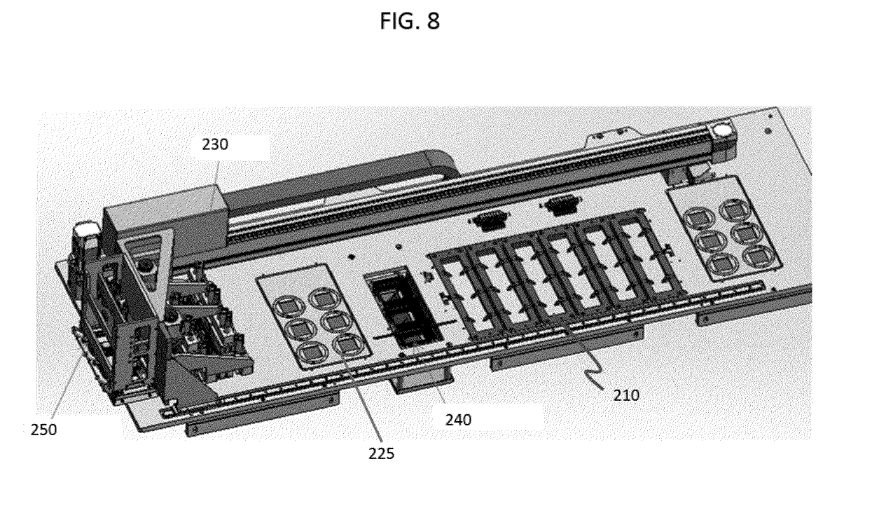

FIG. 8 is a top perspective view of a portion of the contactor vision alignment system shown in FIG. 1, according to one embodiment. In addition to the one or more clamping mechanisms 205, the contactor vision alignment system 200 includes one or more upward-looking cameras 240 configured to view the top contactor assembly 220, one or more downward-looking cameras 250 configured to view the bottom contactor assembly 210, a device tray 225, and an adjustment mechanism 230 configured to move the integrated circuit device 500 and the top contactor assembly 220. The contactor vision alignment system functions as follows.

The contactor vision alignment system 200 includes a controller connected to the upward-looking cameras 240, downward-looking cameras 250, and adjustment mechanism 230. The controller includes a CPU, memory, and data bus, and is programmed to control the adjustment mechanism to perform adjustments to the locations of the integrated circuit device 500 and the top contactor assembly 220 based on data received from the upward-looking cameras 240 and downward-looking cameras 250.

Specifically, the controller is configured to, based on data received from the downward-looking camera and the upward-looking camera: determine an offset (Bary2PogoOff) between the bottom side device contact array and the bottom contactor contact army, cause the adjustment mechanism to align the bottom side device contact array with the bottom contactor contact array based on the determined offset between the bottom side device contact array and the bottom contactor contact array, determine an offset (Pogo2TaryOff) between the top contactor contact array and the top side device contact array, and cause the adjustment mechanism to align the top contactor with respect to the top side device contact array based on the determined offset between the top side device contact array and the top contactor contact array. One example of how the offsets Bary2PogoOff and Pogo2TaryOff are determined is described below.

Before runtime, the controller is configured perform a top vision alignment calibration process that includes: picking the top contactor assembly and moving the top contactor assembly above the upward-looking camera, determining an offset (Cfid2UfidOff) between the at least two top contactor assembly fiducials and the at least two adjustment mechanism fiducials based on data from the upward-looking camera, placing the top contactor assembly into a socket of the bottom contactor assembly, determining an offset (Sfid2CfidOff) between the at least two bottom contactor assembly fiducials and the at least two top contactor assembly fiducials based on data from the downward-looking camera, and calculating an offset (Ufid2SfidOff) between the at least two bottom contactor assembly fiducials and the at least two adjustment mechanism fiducials by adding the determined offset (Cfid2UfidOff) between the at least two top contactor assembly fiducials and the at least two adjustment mechanism fiducials and the determined offset (Sfid2CfidOff) between the at least two bottom contactor assembly fiducials and the at least two top contactor assembly fiducials. After this calibration is complete, the calibrated top and bottom contactor assemblies are correlated to one another using the identification marks, as described above.

Either during runtime or during calibration, the controller is configured to determine an offset (Sfid2PogoOff) between the bottom contactor contact array and the at least two bottom contactor assembly fiducials, based on data from the downward-looking camera.

For IC device bottom vision alignment during runtime, the controller causes the adjustment mechanism to pick up the IC device (e.g., using the top contactor assembly) and move it above the upward-looking camera. The controller determines an offset (Ufid2BaryOff) between the bottom side device contact array and the at least two adjustment mechanism fiducials while the integrated circuit device is held by the adjustment mechanism, based on data from the upward-looking camera. The controller then determines the offset (Bary2PogoOff) between the bottom side device contact array and the bottom contactor contact array by adding the offset (Ufid2BaryOff) between the bottom side device contact array and the at least two adjustment mechanism fiducials, the offset (Ufid2SfidOff) between the at least two bottom contactor assembly fiducials and the at least two adjustment mechanism fiducials (determined during calibration), and the offset (Sfid2PogoOff) between the bottom contactor contact array and the at least two bottom contactor assembly fiducials (determined during calibration or earlier during runtime). The controller then causes the adjustment mechanism to align the bottom side device contact array with the bottom contactor contact array based on the determined offset between the bottom side device contact army and the bottom contactor contact array, and place the IC device into the bottom contactor assembly.

For IC top vision alignment during runtime, the controller causes the adjustment mechanism to pick up the top contactor assembly and move it above the upward-looking camera. The controller is configured to determine an offset (Pogo2UfidOff) between the top contactor contact array and the at least two adjustment mechanism fiducials while the top contactor assembly is held by the adjustment mechanism, based on data from the upward-looking camera. The downward-looking camera then views the bottom contactor assembly with the IC device located therein. The controller then determines an offset (Sfid2TaryOff) between the top side device contact array and the at least two bottom contactor assembly fiducials while the integrated circuit device is located in the bottom contactor assembly, based on data from the downward-looking camera. The controller then determines the offset (Pogo2TaryOff) between the top contactor contact array and the top side device contact array by adding the offset (Pogo2UfidOff) between the top contactor contact array and the at least two adjustment mechanism fiducials, the offset (Sfid2TaryOff) between the top side device contact array and the at least two bottom contactor assembly fiducials, and the offset (Ufid2SfidOff) between the at least two bottom contactor assembly fiducials and the at least two adjustment mechanism fiducials (determined during calibration). The controller than causes the adjustment mechanism to align the top contactor with respect to the top side device contact array based on the determined offset between the top side device contact array and the top contactor contact array, and to press the top contactor contact array against the IC device top side contact array. Then the top contactor assembly is clamped to the bottom contactor assembly using the locking mechanism, and the entire clamping apparatus, with the IC device therein, can be moved to the integrated circuit (IC) device testing system for IC device testing.

Verifications of the calibration may be performed. For example, after the adjustment mechanism corrects for the offset of the top contactor assembly, the upward-looking camera can be used to verify the correction and determine the offset (Cfid2UfidOff) between the at least two top contactor assembly fiducials and the at least two adjustment mechanism fiducials. After placing the top contactor assembly in the bottom contactor assembly, the downward-looking camera can be used to determine the offset (Sfid2CfidOff) between the at least two bottom contactor assembly fiducials and the at least two top contactor assembly fiducials. Then, the offset (Ufid2SfidOff) between the at least two bottom contactor assembly fiducials and the at least two adjustment mechanism fiducials can be calculated and compared to the previously determined calibration value. If the difference between the newly determined offset (Ufid2SfidOff) and the previously determined offset (Ufid2SfidOff) is with a predetermined tolerance value, then runtime is continued. Otherwise, the verification process is repeated. If the difference is within tolerance any two of three verification attempts, then the offset (Ufid2SfidOff) is updated to be the average of the two within-tolerance values. Otherwise, the system is stopped for trouble shooting.

Verification of runtime offset determines can also be verified. For example, after the adjustment mechanism corrects for the offset (Pogo2TaryOff) between the top contactor contact array and the top side device contact array, the upward looking camera can be used to determine the offset (Cfid2UfidOff) between the at least two top contactor assembly fiducials and the at least two adjustment mechanism fiducials. And after the top contactor assembly is placed in the bottom contactor assembly, the downward-looking camera can be used to determine the offset (Sfid2CfidOff) between the at least two bottom contactor assembly fiducials and the at least two top contactor assembly fiducials. Then, the controller can calculate the offset (Ufid2SfidOff) between the at least two bottom contactor assembly fiducials and the at least two adjustment mechanism fiducials by adding the offset (Cfid2UfidOff) between the at least two top contactor assembly fiducials and the at least two adjustment mechanism fiducials and the offset (Sfid2CfidOff) between the at least two bottom contactor assembly fiducials and the at least two top contactor assembly fiducials. This newly determined offset (Ufid2SfidOff) can be compared with the previously determined value of (Ufid2SfidOff). If the difference between the newly determined offset (Ufid2SfidOff) and the previously determined offset (Ufid2SfidOff) is with a predetermined tolerance value, then runtime is continued. Otherwise, the verification process is repeated. If the difference is within tolerance any two of three verification attempts, then the offset (Ufid2SfidOff) is updated to be the average of the two within-tolerance values. Otherwise, the system is stopped for trouble shooting.

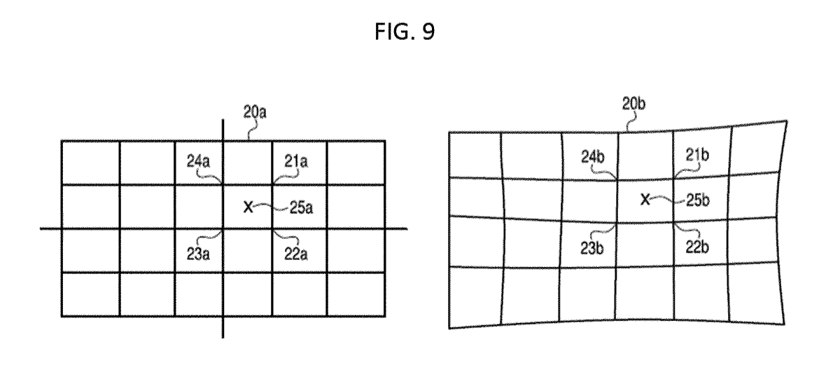

To linearize non-linear error of the alignment system, an imaged non-linear grid motion of the actuator may be mapped to an expected linear grid motion based on actuator counts. FIG. 9 shows an example of an expected linear grid motion 20a of the actuators and an imaged non-linear grid motion 20b of the actuators during the calibration process. At each node of the grids 20a, 20b, a one-to-one mapping may be used. For example, to estimate a point 25b (defined by X^{t}, Y^{t}), a piecewise linear transform that maps four nodes 21b, 22b, 23b, 24b of the non-linear grid (defined by X′₁,Y′₁,X′₂,Y′₂ . . . ) to the corresponding nodes 21a, 22a, 23a, 24a of the expected linear grid (defined by X₁,Y₁,X₂,Y₂ . . . ) may be used. The eight-degree transform function may then be expressed as equation (1) as follows:

$${X}^{′} = \frac{( AX + CY + E )}{( 1 - GX - HY )}$$

$${Y}^{′} = \frac{( BX + DY + F )}{( 1 - GX - HY )}$$

The above can be further written as equation (2) as follows:

X′=GX′X|HX′Y|AX|CY|E

Y′=GY′X+HY′Y+BX+DY+F

By referencing the four nodes of the linear grid 20a and the non-linear grid 20b, the linear transforms (A,B,C,D,E,F,G,H) can be determined by expressing the above equation in matrix form as equation (3):

$$[ \begin{matrix}{X}_{1}^{′} \\ {X}_{2}^{′} \\ {X}_{3}^{′} \\ {X}_{4}^{′} \\ {Y}_{1}^{′} \\ {Y}_{2}^{′} \\ {Y}_{3}^{′} \\ {Y}_{4}^{′}\end{matrix} ] = [ \begin{matrix}{X}_{1} & 0 & {Y}_{1} & 0 & 1 & 0 & {X}_{1}^{′} {X}_{1} & {X}_{1}^{′} {Y}_{1} \\ {X}_{2} & 0 & {Y}_{2} & 0 & 1 & 0 & {X}_{2}^{′} {X}_{2} & {X}_{2}^{′} {Y}_{2} \\ {X}_{3} & 0 & {Y}_{3} & 0 & 1 & 0 & {X}_{3}^{′} {X}_{3} & {X}_{3}^{′} {Y}_{3} \\ {X}_{4} & 0 & {Y}_{4} & 0 & 1 & 0 & {X}_{4}^{′} {X}_{4} & {X}_{4}^{′} {Y}_{4} \\ 0 & {X}_{1} & 0 & {Y}_{1} & 0 & 1 & {Y}_{1}^{′} {X}_{1} & {Y}_{1}^{′} {Y}_{1} \\ 0 & {X}_{2} & 0 & {Y}_{2} & 0 & 1 & {Y}_{2}^{′} {X}_{2} & {Y}_{2}^{′} {Y}_{2} \\ 0 & {X}_{3} & 0 & {Y}_{3} & 0 & 1 & {Y}_{3}^{′} {X}_{3} & {Y}_{3}^{′} {Y}_{3} \\ 0 & {X}_{4} & 0 & {Y}_{4} & 0 & 1 & {Y}_{4}^{′} {X}_{4} & {Y}_{4}^{′} {Y}_{4}\end{matrix} ] [ \begin{matrix}A \\ B \\ C \\ D \\ E \\ F \\ G \\ H\end{matrix} ]$$

Once the linear transforms are determined using the above matrix equation, a point within the four-node grid space of the non-linear grid 20b may be estimated using point matching with the four-node grid space of the linear grid 20a as shown in equation (1) above. Estimation error in the above transform may be controlled by the sizes of the grids defined by the four nodes, where the smaller the individual grid, the smaller the given error.

While the preferred embodiments of the devices and methods have been described in reference to the environment in which they were developed, they are merely illustrative of the principles of the inventions. Modification or combinations of the above-described assemblies, other embodiments, configurations, and methods for carrying out the invention, and variations of aspects of the invention that are obvious to those of skill in the art are intended to be within the scope of the claims. In addition, where this application has listed the steps of a method or procedure in a specific order, it may be possible, or even expedient in certain circumstances, to change the order in which some steps are performed, and it is intended that the particular steps of the method or procedure claim set forth below not be construed as being order-specific unless such order specificity is expressly stated in the claim.

What is claimed is:

1. A system comprising:
a bottom contactor assembly comprising a bottom contactor contact array;
a top contactor assembly comprising a top contactor contact array; and
a contactor vision alignment system located separate from a test site of an integrated circuit device testing system, the contactor vision alignment system comprising:
a downward-looking camera configured to view the bottom contactor assembly,
an upward-looking camera configured to view the top contactor assembly,
an adjustment mechanism configured to move the top contactor assembly, and
a controller configured to, based on data received from the downward-looking camera and the upward-looking camera:
determine an offset between a bottom side integrated circuit device contact array and the bottom contactor contact array,
cause the adjustment mechanism to align the bottom side integrated circuit device contact array with the bottom contactor contact array based on the determined offset between the bottom side device contact array and the bottom contactor contact array,
determine an offset between the top contactor contact array and a top side integrated circuit device contact array, and
cause the adjustment mechanism to align the top contactor with respect to the top side device contact array based on the determined offset between the top side device contact array and the top contactor contact array.

2. The system of claim 1, wherein:
the top contactor assembly comprises at least two top contactor assembly fiducials, each of which is visible from both a top side and a bottom side of the top contactor assembly,
the bottom contactor assembly comprises at least two bottom contactor assembly fiducials,
the adjustment mechanism comprises at least two adjustment mechanism fiducials,
the controller is configured to determine the offset between the bottom side device contact array and the bottom contactor contact array by performing steps that include:
determining an offset between the bottom contactor contact array and the at least two bottom contactor assembly fiducials, based on data from the downward-looking camera, and
determining an offset between the bottom side device contact array and the at least two adjustment mechanism fiducials while the integrated circuit device is held by the adjustment mechanism, based on data from the upward-looking camera, and
the controller is configured to determine the offset between the top contactor contact array and the top side device contact array by performing steps that include:
determining an offset between the top contactor contact array and the at least two adjustment mechanism fiducials while the top contactor assembly is held by the adjustment mechanism, based on data from the upward-looking camera, and
determining an offset between the top side device contact array and the at least two bottom contactor assembly fiducials while the integrated circuit device is located in the bottom contactor assembly, based on data from the downward-looking camera.

3. The system of claim 2,
wherein the controller is further configured perform a top vision alignment calibration process that includes:
picking the top contactor assembly and moving the top contactor assembly above the upward-looking camera,
determining an offset between the at least two top contactor assembly fiducials and the at least two adjustment mechanism fiducials, based on data from the upward-looking camera,
placing the top contactor assembly into the bottom contactor assembly,
determining an offset between the at least two bottom contactor assembly fiducials and the at least two top contactor assembly fiducials, based on data from the downward-looking camera, and
calculating an offset between the at least two bottom contactor assembly fiducials and the at least two adjustment mechanism fiducials, based on the determined offset between the at least two top contactor assembly fiducials and the at least two adjustment mechanism fiducials and the determined offset between the at least two bottom contactor assembly fiducials and the at least two top contactor assembly fiducials.

4. The system of claim 3, wherein the controller is configured to use the calculated offset between the at least two bottom contactor assembly fiducials and the at least two adjustment mechanism fiducials in both (i) determining the offset between the bottom side device contact array and the bottom contactor contact array, and (ii) determining the offset between the top contactor contact array and the top side device contact array.

5. The system of claim 1, further comprising:
a locking mechanism configured to attach the top and bottom contactor assemblies to each other while the integrated circuit device is located between the top contactor and the bottom contactor, and while the bottom side device contact array is connected to the bottom contactor contact array and the top side device contact array is connected to the top contactor contact array.

6. A method of performing vision alignment of an integrated circuit device, the method comprising:
providing a bottom contactor assembly comprising a bottom contactor contact array;
providing a top contactor assembly comprising a top contactor contact army;
providing a contactor vision alignment system located separate from a test site of an integrated circuit device testing system, the contactor vision alignment system comprising:
a downward-looking camera configured to view the bottom contactor assembly,
an upward-looking camera configured to view the top contactor assembly,
an adjustment mechanism configured to move the top contactor assembly, and
a controller;
using the controller, and based on data received from the downward-looking camera and the upward-looking camera:
determining an offset between the bottom side device contact array and the bottom contactor contact array,
causing the adjustment mechanism to align the bottom side device contact array with the bottom contactor contact array based on the determined offset between the bottom side device contact army and the bottom contactor contact array,
determining an offset between the top contactor contact array and the top side device contact array, and
causing the adjustment mechanism to align the top contactor with respect to the top side device contact array based on the determined offset between the top side device contact army and the top contactor contact array.

7. The method of claim 6, wherein:
the top contactor assembly comprises at least two top contactor assembly fiducials, each of which is visible from both a top side and a bottom side of the top contactor assembly,
the bottom contactor assembly comprises at least two bottom contactor assembly fiducials,
the adjustment mechanism comprises at least two adjustment mechanism fiducials,
the step of determining the offset between the bottom side device contact array and the bottom contactor contact array includes:
determining an offset between the bottom contactor contact array and the at least two bottom contactor assembly fiducials, based on data from the downward-looking camera, and
determining an offset between the bottom side device contact array and the at least two adjustment mechanism fiducials while the integrated circuit device is held by the adjustment mechanism, based on data from the upward-looking camera, and
the step of determining the offset between the top contactor contact array and the top side device contact array includes:
determining an offset between the top contactor contact array and the at least two adjustment mechanism fiducials while the top contactor assembly is held by the adjustment mechanism, based on data from the upward-looking camera, and
determining an offset between the top side device contact array and the at least two bottom contactor assembly fiducials while the integrated circuit device is located in the bottom contactor assembly, based on data from the downward-looking camera.

8. The method of claim 7, further comprising
performing a top vision alignment calibration process that includes:
picking the top contactor assembly and moving the top contactor assembly above the upward-looking camera,
determining an offset between the at least two top contactor assembly fiducials and the at least two adjustment mechanism fiducials, based on data from the upward-looking camera,
placing the top contactor assembly into the bottom contactor assembly,
determining an offset between the at least two bottom contactor assembly fiducials and the at least two top contactor assembly fiducials, based on data from the downward-looking camera, and
calculating an offset between the at least two bottom contactor assembly fiducials and the at least two adjustment mechanism fiducials, based on the determined offset between the at least two top contactor assembly fiducials and the at least two adjustment mechanism fiducials and the determined offset between the at least two bottom contactor assembly fiducials and the at least two top contactor assembly fiducials.

9. The method of claim 8, wherein the calculated offset between the at least two bottom contactor assembly fiducials and the at least two adjustment mechanism fiducials is used in both (i) determining the offset between the bottom side device contact array and the bottom contactor contact array, and (ii) determining the offset between the top contactor contact array and the top side device contact array.

10. The method of claim 6, further comprising:
using a locking mechanism to attach the top and bottom contactor assemblies to each other while the integrated circuit device is located between the top contactor and the bottom contactor, and while the bottom side device contact array is connected to the bottom contactor contact array and the top side device contact array is connected to the top contactor contact array; and
transferring top and bottom contactor assemblies, with the integrated circuit device located therebetween, to a test site of an integrated circuit device testing system.

11. A clamping mechanism configured to hold an integrated circuit device having a bottom side device contact array and a top side device contact array, the clamping mechanism comprising:
a bottom contactor assembly comprising:
a bottom contactor assembly frame, and
a bottom contactor attached to the bottom contactor assembly frame, the bottom contactor comprising a bottom contactor contact array;
a top contactor assembly comprising:
a clamping apparatus, and
a top contactor fixed to the clamping apparatus, the top contactor comprising a top contactor contact array; and
a locking mechanism configured to removably attach the top and bottom contactor assemblies to each other while the integrated circuit device is located between the top contactor and the bottom contactor, and while the bottom side device contact array is connected to the bottom contactor contact array and the top side device contact array is connected to the top contactor contact array.

12. The clamping mechanism of claim 11,
wherein the clamping apparatus of the top contactor assembly comprises:
a clamping plate configured to contact the bottom contactor assembly frame when the top and bottom contactor assemblies are attached to each other,
a mounting plate to which the top contactor is fixed, and
a vertical compliance member configured to allow the mounting plate and the top contactor to move vertically with respect to the clamping plate, so as to preload the top contactor when the top and bottom contactor assemblies are attached to each other.

13. The clamping mechanism of claim 12, wherein the vertical compliance member is a flexure.

14. The clamping mechanism of claim 11, wherein the locking mechanism comprises an electromagnetic device.

15. The clamping mechanism of claim 12, wherein the locking mechanism comprises an electromagnetic device located in the clamping plate.

16. The clamping mechanism of claim 11, wherein the locking mechanism comprises a vacuum device, an air pressure device, or a mechanical latch.

17. The clamping mechanism of claim 11, wherein the top contactor assembly comprises at least two top contactor assembly fiducials, each of which is visible from both a top side and a bottom side of the top contactor assembly.

18. The clamping mechanism of claim 17, wherein the at least two top contactor assembly fiducials are located on the top contactor.

19. The clamping mechanism of claim 18, wherein the top contactor comprises at least two projections that extend laterally beyond a periphery of the clamping apparatus, and each of the at least two top contactor assembly fiducials is located on a respective one of the projections at a location outside the periphery of the clamping apparatus.

20. The clamping mechanism of claim 17, wherein the bottom contactor assembly comprises at least two bottom contactor assembly fiducials.

21. The clamping mechanism of claim 11, wherein the clamping mechanism is movable as a unit while the top and bottom contactor assemblies are attached to each other via the locking mechanism.
